(19) United States
(12) Patent Application Publication
(10) Pub. No.: US 2015/0115303 A1
(43) Pub. Date: Apr. 30, 2015

(54) LED Module with Circuit Board

(71) Applicants: Tridonic Jennersdorf GmbH, Jennersdorf (AT); AT & S Austria Technologie & Systemtechnik Aktiengesellschaft, Leoben (AT)

(72) Inventors: Peter Pachler, Graz (AT); Anna Szucs, Jennersdorf (AT); Gregor Langer, Wolfnitz (AT); Christian Sommer, Graz (AT)

(73) Assignees: Tridonic Jennersdorf GmbH, Jennersdorf (AT); AT&S Austria Techmologie & Systemtechnik Aktiengesellchaft, Leoben (AT)

(21) Appl. No.: 14/398,027

(22) PCT Filed: Mar. 7, 2013
(86) PCT No.: PCT/EP2013/054617

§ 371 Date: Dec. 8, 2014

(30) Foreign Application Priority Data
Apr. 30, 2012 (DE) 10 2012 207 171.7
Jul. 26, 2012 (DE) 10 2012 213 178.7

(51) Int. Cl. H01L 33/46

(52) U.S. Cl. CPC H01L 33/46; H01L 2933/0058; H01L 2933/0025
USPC 257/98; 438/29

(57) ABSTRACT

The present invention relates to an LED module 10, a circuit board 1, and a method for coating the circuit board 1 that is used in an LED module 10. The circuit board 1 is used particularly for reflecting light emitted by at least one LED chip of the LED module 10. The at least one LED chip 6 is located on a carrier plate 5 in a cut-out 2 of the circuit board 1. To increase the light yield of the LED module 10, the circuit board 1 is sprayed with a highly reflective layer 4. The layer 4 can be an ink provided with reflective particles, for example, which is sprayed on using an ink jet printing method. The LED module can additionally have at least one colour conversion element 7, 8, 9, which is preferably positioned in or above the at least one cut-out 2 of the circuit board 1. Finally; positioning elements 12, 13 can improve the assembly of the LED module 10, particularly the alignment of the circuit board 1 and the carrier plate 5.

The present invention encompasses an LED module comprising a coated circuit board, and the coated circuit board itself. The coated circuit board serves to direct part of the light emitted laterally by an LED chip of the LED module in the direction of the normal axis of the LED module. In particular, the following invention also presents a method for coating a circuit board of an LED module.

It is known in the prior art to install a circuit board having a cutout in an LED module in order to reflect toward the outside light emitted by an LED chip of the LED module and to predefine an emission direction. Such a circuit board is typically composed of a plastic whose surface is covered with a copper track. The copper track is suitable for reflecting light, but the efficiency is low. The LED chip is positioned in the LED module in the cutout of the circuit board in such a way that it radiates light from the rear through the cutout out of the LED module.

However, such a copper track on the surface of a plastic material does not have satisfactory reflection properties over the entire spectral range of visible light. The reflection properties are insufficient particularly in the spectral range of blue light.

The present invention therefore proposes the basic concept of providing a surface of a circuit board with a highly reflective layer. However, conventional coating processes, such as screen printing or curtain coating, for example, are not well suited to this since they do not achieve a satisfactory uniform coating particularly of the boundary walls of cutouts of the circuit board. Moreover, there is the risk that the rear side of the circuit board will be contaminated in an undefined manner with the material to be applied during such processes. Although screen printing processes can initially be used for relatively coarse structures, they are unsuitable for finer structures.

The present invention addresses the problem of improving all the abovementioned disadvantages of the prior art. In particular, a problem addressed by the present invention is that of increasing the luminous efficiency of an LED module. For this purpose, the intention is specifically to produce a circuit board having improved reflection properties for an LED module. Moreover, the invention seeks to avoid the disadvantages of conventional processes and methods. In particular, the boundary walls of cutouts in a circuit board are intended to be provided with good reflection properties.

The present invention solves the abovementioned problems in accordance with the independent claims. The dependent claims advantageously develop the central concept of the invention further.

In particular, the invention is directed to an LED module comprising a circuit board having at least one cutout and a surface on its front side, wherein a highly reflective layer is applied to the surface, a carrier plate with an LED chip fitted thereto, wherein the carrier plate is fitted to the rear side of the circuit board, such that the LED chip can radiate light from the rear through the cutout of the circuit board.

The highly reflective layer can improve the reflection properties of the circuit board over the entire spectral range. The highly reflective layer should uniformly covers the surface of the circuit board, in particular including in the cutout of the circuit board. The light radiated from the rear through the cutout can be reflected highly efficiently and thus emerge from the LED module substantially without losses on the front side of the circuit board. The carrier plate is a type of board-in-board (or sub-board) on which the LED chip is fitted. The luminous efficiency of the LED module can be significantly increased by means of the highly reflective layer. The surface of the circuit board can be conductive or can have a conductive structure, such as copper tracks, for example. The highly reflective layer can be applied on/above the copper tracks. However, the copper tracks can also be situated on the surface on the rear side of the circuit board, such that the highly reflective layer is sprayed onto a non-conductive surface on the front side of the circuit board.

Advantageously, the highly reflective layer comprises a UV-stable and/or temperature-stable material.

This ensures both the durability against environmental influences and the service life of the LED module.

Advantageously, the highly reflective layer is applied by spraying, dip coating, printing or by photolithography. A uniform and thin covering can be achieved as a result.

Advantageously, the highly reflective layer is a layer composed of an ink which is based on highly reflective particles. The particles can be based on ceramic, for example. In this case, the highly reflective particles should be on the micrometers or nanometers scale, and should be distributed as uniformly as possible in the ink. Such an ink can be applied very well in order to obtain a uniform coating thickness. Furthermore, such an ink has good reflection properties over the entire spectral range of visible light, in particular in the wavelength range of 420 nm-690 nm. Such an ink can advantageously be sprayed onto the circuit board by specific methods, as will be described further below.

Advantageously, the highly reflective layer is applied with a uniform thickness on the surface including on the lateral boundary walls of the at least one cutout.

As a result, the luminous efficiency of the LED module can be increased since, in the LED module, in particular the lateral boundary walls of the at least one cutout reflect the light from the at least one LED chip toward the outside.

Advantageously, the highly reflective layer is 5 to 50 μm thick.

Typical cutouts in a circuit board are produced for example by drilled holes or milled sections and have a roughness in the range of approximately 1 to 50 μm, preferably 10 to 50 μm. The surface of the circuit board can be a conductive copper track, for example, which can likewise cover the walls of the drilled holes or milled sections and already substantially compensates for the roughnesses. The abovementioned thickness of the highly reflective layer is advantageous, in order to obtain not only a very thin layer, but also a very uniform layer, despite said roughnesses.

Advantageously, the lateral boundary walls of the at least one cutout form an angle with the surface of the circuit board, which angle is in a range of approximately 10° to 90°, preferably in a range of approximately 30° to 60°, even more preferably approximately 40° to 50°.

As a result of the angle of the boundary walls, the light is reflected out of the LED module efficiently.

The present invention furthermore relates to a method for coating a circuit board of an LED module, wherein the circuit board has at least one cutout and a surface and a highly reflective layer is applied to the surface.

Such a method allows a circuit board to be produced for an LED module, which circuit board has better reflection properties over the entire spectral range than a conventional circuit board. In addition, such a coated circuit board is simple and cost-effective to produce and the method according to the invention can achieve a very uniform coating. As a result, the luminous efficiency of an LED module containing the circuit board can be significantly increased.

Advantageously, the highly reflective layer is sprayed on by means of an inkjet printing method.

An inkjet printing method is an inexpensive alternative to conventional coating processes. Moreover, the boundary walls of the at least one cutout can be sprayed uniformly with the highly reflective layer by means of such a method, as a result of which the reflection properties of the circuit board overall are improved. The inkjet printing method can also prevent contamination of regions that are not to be coated.

Advantageously, the highly reflective layer is formed from at least one dimensionally stable and/or temperature-stable material.

Advantageously, the highly reflective layer is formed at least from an ink based on highly reflective particles.

Such a layer can be sprayed on well by an inkjet printing method and additionally has a high reflectivity.

Advantageously, the highly reflective particles have a diameter which is in a range of approximately 100 nm to 10 μm, more preferably 100 nm to 2 μm, most preferably 400 nm to 2 μm average grain size.

Such particles can be distributed extremely uniformly in the ink, as a result of which the ink can be sprayed on uniformly and simply by an inkjet printing method. The particles nevertheless impart an improved reflectivity to the layer resulting from the ink.

Advantageously, the highly reflective layer is sprayed on with a thickness of approximately 5 to 50 μm.

The layer thus becomes uniformly thick including on the boundary walls of the cutout. Unevennesses which arise as a result of typical methods used to produce the at least one cutout can be compensated for.

Advantageously, the highly reflective layer is sprayed onto the surface by means of a spraying jet, wherein the spraying jet can be aligned.

This is particularly advantageous if the angles of the boundary walls with the principal plane of the circuit board are very steep. In a limiting case, the boundary walls are situated at 90° steep angles with respect to the surface of the circuit board. However, a uniform coating of the boundary walls can still be achieved by means of the alignment of the spraying jet.

Advantageously, the alignment of the spraying jet is chosen and/or varied such that the highly reflective layer is also sprayed uniformly onto the lateral boundary walls of the at least one cutout.

That is to say that the direction of the spraying jet can be altered during the method for spraying, for example an inkjet printing method. It is also conceivable to carry out a layer thickness measurement during the spraying process and to alter the spraying jet on the basis of the result of the measurement in such a way that unevennesses in the sprayed-on layer are immediately compensated for.

The present invention also relates to an LED module, comprising a circuit board having at least one cutout and a surface on its front side, wherein the surface of the circuit board is coated by a method as described above, a carrier plate with an LED chip fitted thereto, wherein the carrier plate is fitted to the rear side of the circuit board, such that the LED chip can radiate from the rear through the cutout of the circuit board.

The present invention also relates to an LED module, comprising a circuit board having at least one cutout, a carrier plate with an LED chip fitted thereto, wherein the carrier plate is fitted to the rear side of the circuit board, such that the LED chip can radiate light from the rear through the cutout of the circuit board, wherein a color conversion element is fitted to the circuit board, preferably in or above the cutout, said color conversion element being designed at least partly to absorb light of a first wavelength from the at least one LED chip and thereupon itself to emit light of a second wavelength.

An LED module having this construction is for example a simple solution for producing white light by combining, for example, a blue LED chip and a yellow or green and red phosphor.

The present invention also relates to an LED module, comprising a circuit board having at least one cutout, a carrier plate with an LED chip fitted thereto, wherein the carrier plate is fitted to the rear side of the circuit board, such that the LED chip can radiate light from the rear through the cutout of the circuit board, wherein the LED module furthermore comprises a positioning unit designed to align the circuit board and the carrier plate relative to one another during fitting.

An LED module having this construction simplifies the assembly and improves the coordination of the individual components of the LED module in relation to one another. The efficiency of the LED module can be increased as a result.

The abovementioned embodiments of an LED module can also advantageously be combined with one another. Particularly the increased reflectivity for visible light that is achieved by means of the coated circuit board is beneficial to an LED module comprising a blue LED chip and a color conversion element for generating white light. This is because the reflectivity in the blue range, in particular, is significantly improved by the highly reflective layer as described above. The luminous efficiency of white light is increased as a result. The luminous efficiency can be improved further by means of the optimum alignment of the carrier plate and the coated circuit board during the assembly of the LED module.

The present invention also relates to a circuit board for an LED module having at least one cutout and a surface on its front side, wherein a highly reflective layer is applied to the surface.

The highly reflective layer improves the reflection properties of the circuit board over the entire spectral range. The highly reflective layer should uniformly cover the surface of the circuit board, in particular including in the cutout of the circuit board.

Advantageously, the highly reflective layer is a layer composed of an ink which is based on highly reflective particles.

Advantageously, the highly reflective layer is sprayed on the surface and on the lateral boundary walls of the at least one cutout.

Advantageously, the highly reflective layer is approximately 5 to 50 μm thick.

The circuit board is suitable for the rear-side fitting of a carrier plate with an LED chip fitted thereto, such that the LED chip can radiate light from the rear through the cutout of the circuit board.

Overall, therefore, the present invention achieves the effect that the luminous efficiency of an LED module can be significantly increased if a circuit board is installed as described or is coated as described.

The present invention is described in detail below with reference to the accompanying figures.

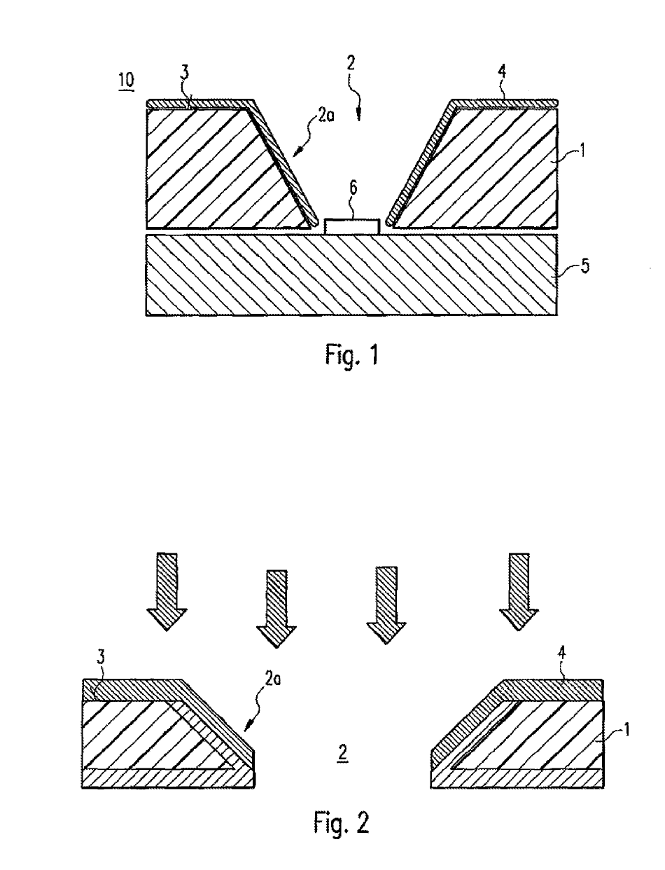

FIG. 1 shows an LED module according to the present invention comprising a coated circuit board.

FIG. 2 shows how a circuit board is coated by a method according to the present invention.

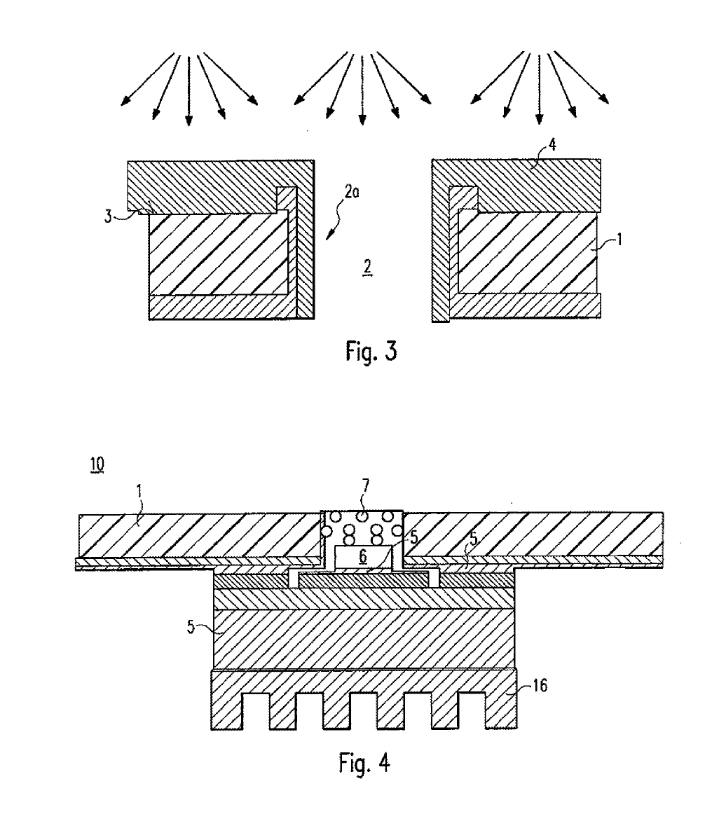

FIG. 3 shows how a circuit board is coated by a method according to the present invention.

FIG. 4 shows an LED module according to the present invention comprising a color conversion element.

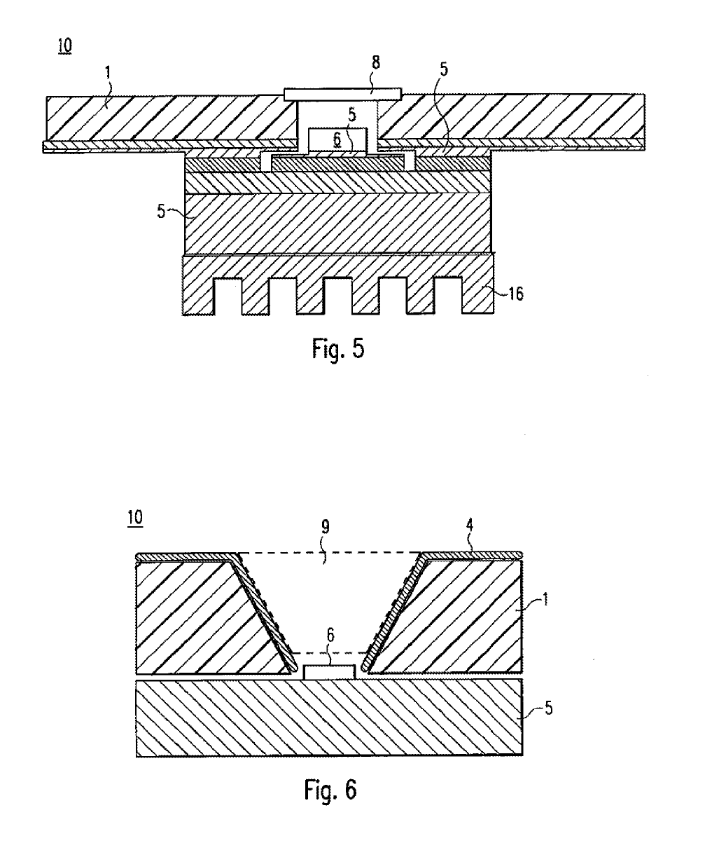

FIG. 5 shows an LED module according to the present invention comprising a color conversion element.

FIG. 6 shows an LED module according to the present invention comprising a color conversion element.

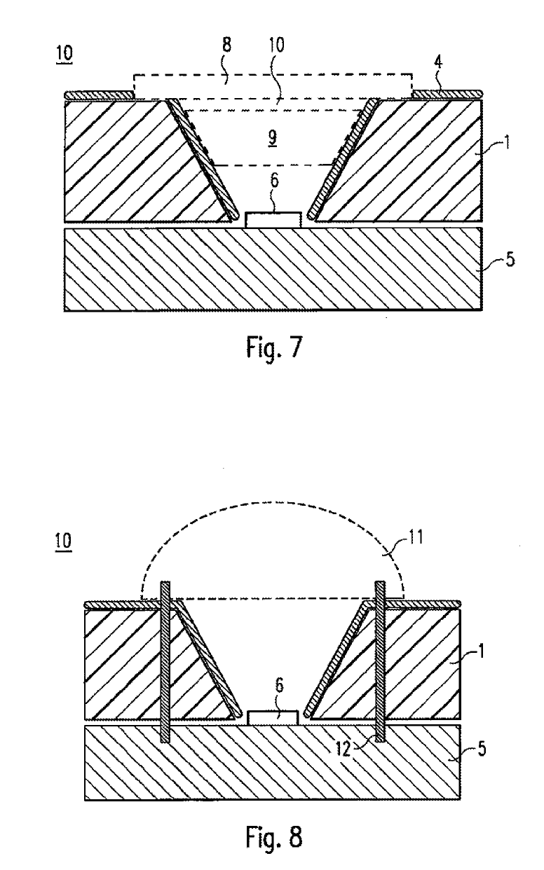

FIG. 7 shows an LED module according to the present invention comprising color conversion elements.

FIG. 8 shows an LED module according to the present invention comprising positioning elements.

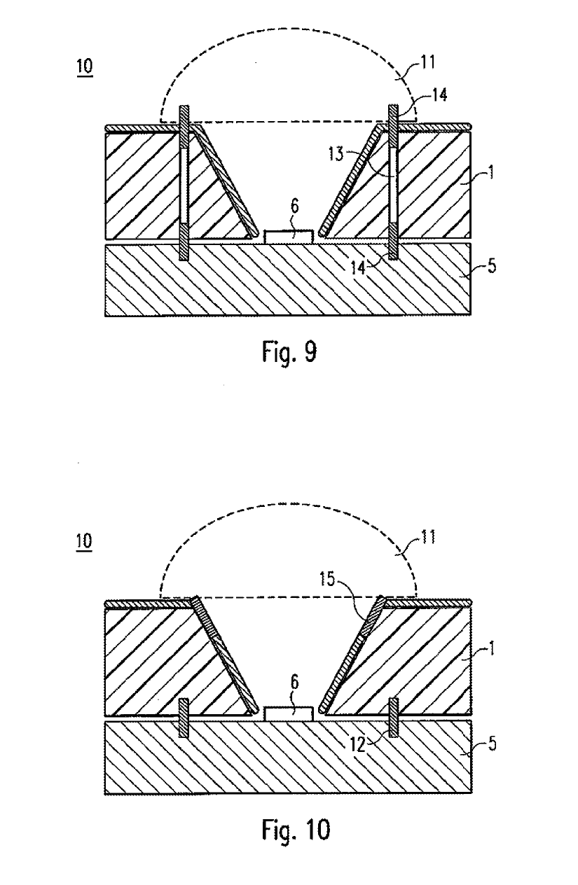

FIG. 9 shows an LED module according to the present invention comprising positioning elements.

FIG. 10 shows an LED module according to the present invention comprising positioning elements.

FIG. 1 shows an LED module 10 of the present invention, and a circuit board 1 of the present invention. The circuit board 1 is part of the LED module 10 but also individually encompassed by the invention. The LED module 10 consists of at least one LED chip 6 applied on a carrier plate 5. The at least one LED chip 6 can be for example a conventional LED, an OLED, an arrangement of a plurality of LEDs or an LED system. A plurality of LEDs can emit either light of the same color or light of different colors. The at least one LED chip 6 can be applied on the carrier plate 5 by being soldered on, adhesively bonded on, plugged on or clamped in. For this purpose, the carrier plate 5 can have, if appropriate, suitable receptacle means for the at least one LED chip 6.

The carrier plate can be constructed in a multilayered fashion. The carrier plate 5 can contain materials which contain, for example, aluminum, gold, palladium, nickel and/or a dielectric. The at least one LED chip 6 is fitted on a surface on the front side of the carrier plate 5, i.e. a surface in the direction of the emission side of the LED module 10. The carrier plate 5 is in turn fitted to the rear side (as viewed in the light emission direction) of a circuit board 1. For this purpose, the carrier plate 5 can be adhesively bonded to, soldered to, or plugged onto, the circuit board 1. In this case, a conductive material of the carrier plate 5, for example a copper layer, can be electrically connected to the circuit board 1. Furthermore, a heat sink 16 can be fitted to the carrier plate 5 on the rear side, in order to dissipate heat from the at least one LED chip 6. The heat sink can be equipped with cooling lamellae, for example.

The at least one LED chip 6 is positioned in at least one cutout 2 of the circuit board 1. The cutout 2 can be a drilled hole, or can be a recess, which is produced as early as during the production of the circuit board 1. The at least one LED chip 6 is positioned behind or in the cutout 2 in such a way that the light emitted by it is emitted from the rear through the cutout 2 of the circuit board 1 from the front side of the LED module 10. The cutout 2 in the circuit board 1 serves as a means for reflecting and for guiding the emitted light. As a result, the light emerges from the LED module 10 in a directional manner. The electronic driving of the at least one LED chip 6 is guided on or in the carrier plate 5.

The circuit board 1 preferably consists of a plastic material, for example of an FR4 glass-fiber-reinforced epoxy. The thermal conductivity of the circuit board is preferably in a range of 0.1 to 1 W/mK, more preferably 0.2 to 0.4 W/mK. The thickness of the circuit board can be between 0.1 and 2 mm. The circuit board 1 is generally covered with a metallic track, for example a copper track, on one of its surfaces (i.e. on its front side or rear side). However, other suitable materials such as aluminum can also be used. The metallic track preferably has a thermal conductivity in a range of approximately 140 to 500 W/mK, more preferably approximately 300 to 500 W/mK, even more preferably approximately 380 W/mK-420 W/mK. Conventional coating methods can be used for applying the metallic track. The metallic track could also additionally be used for conveying current or voltage signals to the at least one LED chip 6.

The boundary walls 2a in the at least one cutout 2 of the circuit board 1 form an angle with the conductive surface 3 of the circuit board 1 on the front side of the LED module 10, which angle is in a range of approximately 10° to 90°, preferably in a range of 30° to 60°, even more preferably 40° to 50°, or is most preferably 45°. As a result, the light emitted by the at least one LED chip 6 can be ideally reflected and guided toward the outside from the LED module 10.

In order to increase the reflectivity of the circuit board 1 further, in particular in order to extend the reflection properties over the entire spectral range, the surface of the circuit board is provided with a highly reflective layer 4. The coated surface can have the conductive copper tracks. However, the conductive copper tracks can also be provided on a different surface of the circuit board 1 than the coated surface. In this case, the highly reflective layer 4 is applied both to the (optionally conductive) surface 3 on the front side of the LED module 10 and on the (optionally conductive) surface 3 on the boundary walls 2a of the cutout 2. The layer can be for example a layer which withstands UV light and withstands temperatures of up to several hundred degrees, without losing its reflection properties. As a result, the reliability of the LED module 10 is increased and the service life is lengthened.

One possibility for embodying such a highly reflective layer 4 is to use therefor an ink admixed with highly reflective particles such as ceramic particles. These particles are preferably on the micrometers or nanometers scale, for example 0.15 to 0.45 μm. The layer is preferably 5 to 50 μm thick, more preferably 20 to 30 μm. The layer increases the reflection properties in the entire visible range, in particular including in the blue spectral range. This is advantageous when generating white light.

The abovementioned ink layer can be applied to the circuit board 1 by means of an inkjet printing method, for example. The size of the particles in the ink is chosen such that the viscosity of the ink can be sprayed onto the surface 3 of the circuit board 1 by means of an inkjet printing method without any problems. Nevertheless, the amount of particles in the ink is also chosen such that very good reflection properties are obtained over the entire desired spectral range. The highly reflective layer 4 is uniformly applied on the oblique boundary walls 2a as well. Even if the boundary walls are very steep, i.e. approximately 90°, a uniform coating with the highly reflective layer 4 can be obtained by means of the method of the present invention.

FIG. 2 illustrates how the method for coating the circuit board 1 of the LED module 10 is performed. The basic concept of the method is one-sided application, preferably spraying of highly reflective materials onto a circuit board 1 having at least one cutout 2. As described above, the method can be an inkjet printing method. As the highly reflective layer 4, an ink based on highly reflective particles composed of ceramic, for example, is then preferably applied as described above.

FIG. 2 reveals how, by means of a directional spraying jet (illustrated by the arrows), a highly reflective layer 4 arises both on the surface 3 on the front side of the LED module or the circuit board 1 and on the preferably oblique boundary walls 2a of the cutout 2. However, the angle can give rise to a different layer thickness. Typical unevennesses in the cutout 2 that are typically produced by drilled holes or other methods (e.g. milling, laser cutting, stamping or the like) are in the range of 1 to 50 μm, preferably 10 to 50 μm. Preferably, therefore, the highly reflective layer 4 is applied with a thickness of between 5 and 50 μm. The highly reflective layer 4 is preferably of the same thickness over the entire surface 3 of the circuit board 1. i.e. including on the boundary walls 2a of the cutout 2.

For this purpose, as shown in FIG. 3, the spraying jet (once again illustrated by the arrows) can be aligned, i.e. also altered in terms of its direction. Consequently, it becomes possible to provide e.g. even very steep boundary walls 2a (for example at an angle of approximately 90°) with a highly reflective layer 4. At the same time, it is possible for the layer to be sprayed on with uniform thickness over the complete surface 3 of the circuit board 1.

The spraying jet can be varied in terms of its direction and/or intensity (i.e. spraying rate of the material) either in a targeted manner or randomly. The spraying jet can also change its direction continuously, such that an equal amount of material is sprayed in all directions at least over a predefined spraying region. Alternatively, however, it is also possible to carry out a layer thickness measurement during spraying. Conventional methods are conceivable here, e.g. a method which measures the present rate of the sprayed material, or a method which measures the layer thickness by means of a laser. The result of such a thickness measurement can be fed back to the apparatus that carried out the method according to the invention. On the basis of the measured thickness of the highly reflective layer 4, the alignment of the spraying jet and/or the intensity thereof can then be altered in order to obtain a uniform layer over the entire surface 3.

As indicated in FIG. 3, it is also possible to use more than one spraying jet for spraying the highly reflective layer 4 onto the circuit board 1. The alignments and/or intensities of the plurality of spraying jets can be altered either jointly or individually. It is also possible to carry out a separate layer thickness measurement for example in each spraying region of the plurality of spraying jets. Consequently, an extremely uniform highly reflective layer 4 could be formed by means of a multiple measurement of the layer thickness and separate driving of the individual spraying jets. In particular, it can also be ensured that the highly reflective layer reliably acquires the desired layer thickness, preferably between 5 and 50 μm.

The method of spraying the highly reflective layer 4 onto the circuit board 1 directionally on one side also prevents the rear side 1 of the circuit board from being contaminated with the highly reflective material in an undefined manner. Specifically, this could have the consequence that the fitting of the carrier plate 5 to the rear side of the circuit board 1 does not function optimally, that the strength of the connection is inadequate or that the rear side of the circuit board 1 has unevennesses which alter the direction of light emission and thus have an adverse influence on the luminous efficiency of the LED module 10. The method can furthermore be used flexibly, such that circuit boards 1 having different cutouts 2 can be coated. In particular circuit boards 1 having cutouts 2 having differently shaped boundary walls 2a, i.e. for example boundary walls that are at different angles with respect to the principal plane of the circuit board 1, can be provided with a uniform layer 4. The method is fast and cost-effective and achieves a high yield.

The circuit board 1, which preferably consists of FR4 as described, forms a so-called board-in-board construction with the carrier plate 5 carrying the at least one LED chip 6. The carrier plate 5 consists of a material which differs from the circuit board material 1 and preferably consists of IMS (Insulated Metal Substrate). A color conversion material 7 can be arranged above the at least one LED chip 6. For this purpose, in one embodiment, the entire cutout 2 can be filled with a color conversion material 7, as shown in FIG. 4. Alternatively or additionally, as shown in FIG. 5, a prefabricated lamina 8 in the form of a ceramic color conversion lamina or a glass provided with phosphor can also be placed over the opening of the cutout 2. Such a color conversion lamina 8 (for example composed of ceramic, phosphor in glass, phosphor in silicone) can be prefabricated externally.

As shown in FIG. 6, a color conversion insert 9 can also be provided, which advantageously has sidewalls adapted to the boundary walls 2a of the cutout 2. That is to say that the sidewalls of the insert 9 should be at the same angle as the boundary walls 2a of the cutout 2 into which the color conversion insert 9 is inserted. In one preferred embodiment, the angle of the sidewalls of the color conversion insert is 45°. Color conversion laminae 8 or color conversion inserts 9 can be produced by corresponding cutting from a color conversion layer, wherein in one preferred embodiment the cutting angle is in each case 45°.

The color conversion insert 9 is inserted into the cutout 2 of the circuit board 1. Since, in one preferred exemplary embodiment, both the color conversion insert 9 and the boundary walls 2a of the circuit board 1 have an angle of 45°, the color conversion insert can be inserted directly into the circuit board 1. Given other angles of between 10° and 90°, the sidewalls of the color conversion insert 9 advantageously have precisely this angle of 10° to 90°. As a result of the fixing of the color conversion insert in the cutout 2 of the circuit board 1, it is also possible, in particular, to accurately align the color conversion insert 9 relative to the at least one LED chip 6.

In a further embodiment, at least two color conversion elements, such as, for instance, a color conversion lamina 8 and a color conversion insert 9 as is shown in FIG. 7, are accommodated on the circuit board 1. However, a color conversion lamina 8 and a filling of the cutout 2 with colorant material as a combination of color conversion elements is also conceivable. The two color conversion elements can consist of the same phosphor material. The concentration of the phosphor material in the two elements can be identical or different. The phosphor material of the lamina 8 can also differ from the phosphor material of the insert 9. In this case, each of the two color conversion elements can also simultaneously contain more than only one type of phosphor material. The two color conversion elements can be fitted one directly above the other or can be separated from one another by a gap 16. The gap 16 can be filled with silicone or some other at least partly transparent material. The gap 16 can also contain air.

In a further embodiment, the construction of the LED module 10 can also be used for setting a desired color temperature. For this purpose, firstly a color conversion lamina 8 and/or color conversion insert 9 are/is fitted and the color locus in a CIE diagram is measured. From a number of further color conversion laminae 8 and/or color conversion inserts 9 of different thicknesses, phosphor concentrations and/or phosphor compositions, that color conversion element is chosen which can best approximate the desired color temperature, i.e. the desired color locus in the CIE diagram.

On the circuit board 1, a further secondary optical unit 11 (diffractive or refractive) or a secondary optical element can also be fitted above the cutout 2, as shown in FIG. 8. This can be, for example, a lens or a glob-top comprising at least one color conversion material and/or scattering particles.

For the board-in-board construction of the present invention, the carrier plate 5 with the LED chips 6 has to be aligned relative to the circuit board 1, and the optional secondary optical unit 11 also has to be aligned relative to the circuit board 1. This can result in inaccuracies in the alignment of the secondary optical unit 11 relative to the at least one LED chip 6. The aim, however, is to align both the carrier plate 5 and the optional secondary optical unit 11 relative to the circuit board 1 such that the smallest possible deviations occur in the alignment of the LED chips 6 relative to the secondary optical unit 11. This can generally be achieved by one or a plurality of markers being integrated in the circuit board 1 and both the carrier plate 5 and the secondary optical unit 11 being aligned relative to said markers during assembly of the board-in-board construction.

In particular, by way of example, as shown in FIG. 8, a suitable positioning unit 12 (for example a marker pin) can be used to align both the board 1 and the plate 5 relative to one another. Said positioning unit 12 can also serve to align the secondary optical unit 11 relative to the circuit board 1. In one preferred embodiment, the positioning unit 12 is fashioned in such a way that both the circuit board 1 and the secondary optical unit 11 are placed onto said positioning unit 12. One example would be at least one positioning pin 12 which projects from the circuit board 1 both at the top side and on the underside, as is illustrated in FIG. 8. Both the carrier plate 5 and the circuit board 1 are inserted in accordance with this at least one positioning pin 12.

In a further embodiment, as shown in FIG. 9, a positioning unit 13 is embodied as a cavity in the circuit board 1. Said cavity 13 can be continuous or can be partly filled with the circuit board material. The carrier plate 5 and the secondary optical unit 11 then have at their underside, for example, a pin-shaped extension 14, the diameter of which is less than or equal to the diameter of the cavity 13 in the circuit board 1. Both the carrier plate 5 and the secondary optical unit 11 can be inserted into the cavity 13 by means of said pin-shaped extension 14.

In a further embodiment, as shown in FIG. 10, the circuit board 1 is aligned relative to the carrier plate 5 by means of a positioning unit 12, 13 according to one of the examples mentioned above (for example a marker, a marking pin or a cavity). By contrast, the alignment of the secondary optical unit 11 relative to the circuit board 1 is effected by virtue of the fact that the secondary optical unit 11 has at its underside a continuation 15 the diameter of which is less than or equal to the diameter of the cutout 2 in the circuit board 1. In one preferred embodiment, the diameter of the continuation 15 at the underside of the secondary optical unit 11 is only insignificantly less than the diameter of the cutout 2 in the circuit board 1, such that the secondary optical unit 11 can be aligned by insertion into the cutout 2 of the circuit board 1.

To summarize, the present invention presents an LED module 10 and a method for coating a circuit board 1 of the LED module 10 by means of which the luminous efficiency of an LED module 10 can be significantly increased. This is achieved by virtue of the fact that the circuit board 1 is additionally coated with a highly reflective layer 4 for better reflection of the light emitted by at least one LED chip 6. In this case, the coating is carried out as a spraying process by which the layer 4 can be applied uniformly and contamination of other areas of the circuit board 1 or of the carrier plate 5 on which the at least one LED chip 6 is fitted can be prevented. The LED module 10 can furthermore comprise at least one color conversion element 7, 8, 9, which is preferably fitted in or above the at least one cutout 2 of the circuit board 1. Finally, positioning elements 12, 13 can provide assistance during the assembly of the LED module 10, in particular during the alignment of the circuit board 1 and the carrier plate 5 with respect to one another.

1. An LED module (10) comprising
a circuit board (1) having at least one cutout (2) and a surface (3) on its front side, wherein a highly reflective layer (4) is applied to the surface (3),
a carrier plate (5) with an LED chip (6) fitted thereto, wherein the carrier plate (5) is fitted to the rear side of the circuit board (1), such that the LED chip can radiate light from the rear through the cutout (2) of the circuit board (1)
wherein the highly reflective layer (4) is a layer composed of an ink which is based on highly reflective particles.

2. The LED module (10) as claimed in claim 1, wherein the highly reflective layer (4) is applied by spraying, dip coating, printing or by photolithography.

3. (canceled)

4. The LED module (10) as claimed in claim 1, wherein the highly reflective layer (4) has a uniform thickness on the surface (3) including on the lateral boundary walls (2a) of the at least one cutout (2).

5. The LED module (10) as claimed in claim 1, wherein the highly reflective layer (4) is approximately 5 to 50 μm thick.

6. The LED module (10) as claimed in claim 1, wherein the lateral boundary walls (2a) of the cutout (2) form an angle with the surface (3) of the circuit board (1), which angle is in a range of approximately 10° to 90°, preferably in a range of approximately 30° to 60°.

7. A method for coating a circuit board (1) of an LED module (10), wherein the circuit board (1) has at least one cutout (2) and a surface (3) and a highly reflective layer (4) is sprayed onto the surface (3).

8. The method as claimed in claim 7, wherein the highly reflective layer (4) is sprayed on by means of an inkjet printing method.

9. The method as claimed in claim 7, wherein the highly reflective layer (4) is formed at least from a UV-stable and/or temperature-stable material.

10. The method as claimed in claim 7, wherein the highly reflective layer (4) is formed at least from an ink based on highly reflective particles.

11. The method as claimed in claim 10, wherein the highly reflective particles have a diameter which is in a range of approximately 1 nm to 2 μm.

12. The method as claimed in claim 7, wherein the highly reflective layer (4) is sprayed on with a thickness of approximately 5 to 50 μm.

13. The method as claimed in claim 7, wherein the highly reflective layer (4) is sprayed onto the surface (3) by means of a spraying jet, wherein the spraying jet can be aligned.

14. The method as claimed in claim 13, wherein the alignment of the spraying jet is chosen and/or varied such that the highly reflective layer (4) is also sprayed uniformly onto the lateral boundary walls (2a) of the at least one cutout (2).

15-17. (canceled)

18. A circuit board (1) for an LED module (10) having at least one cutout (2) and a surface (3) on its front side, wherein a highly reflective layer (4) is sprayed onto the surface (3)
wherein the highly reflective layer (4) is sprayed on the surface (3) and on the lateral boundary walls of the at least one cutout (2).

19. The circuit board (1) as claimed in claim 18, wherein the highly reflective layer is a layer composed of an ink which is based on highly reflective particles.

20. (canceled)

21. The circuit board (10) as claimed in claim 18, wherein the highly reflective layer (4) is approximately 5 to 50 μm thick.

22. The circuit board as claimed in claim 18—for the rear-side fitting of a carrier plate (5) with an LED chip (6) fitted thereto, such that the LED chip can radiate light from the rear through the cutout (2) of the circuit board (1).
